(19) United States
(12) Patent Application Publication
(10) Pub. No.: US 2026/0271602 A1
(43) Pub. Date: Sep. 10, 2026

(54) DISPLAY MODULE AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Yu WANG, Beijing (CN); Guoyi CUI, Beijing (CN); Tao GAO, Beijing (CN)

(21) Appl. No.: 19/480,003

(22) PCT Filed: Apr. 27, 2025
(86) PCT No.: PCT/CN2025/091537

§ 371 Date: Oct. 29, 2025

(30) Foreign Application Priority Data
May 16, 2024 (CN) 202410608477.1

(51) Int. Cl. H10K 59/80

(52) U.S. Cl. CPC H10K 59/8792; H10K 59/879

(57) ABSTRACT

Provided is a display module. The display module includes: a display panel, having an active face and a non-active face opposite to each other, the display panel comprising a plurality of light-emitting regions arranged at intervals, wherein the light-emitting regions are configured to emit light; and a light-dimming assembly, disposed on the active face of the display panel and configured to modulate an angle of emergent light of the display panel, wherein the light-dimming assembly includes: a first insulative layer, provided with openings, wherein the opening at least has a side wall, an orthographic projection of each of the openings on the display panel is disposed at a spacing between two adjacent light-emitting regions; and a light-absorbing layer, comprising a light-absorbing structure, wherein the light-absorbing structure is arranged corresponding to the opening and configured to absorb light.

### CROSS-REFERENCE TO RELATED APPLICATION

This application is a U.S. national stage of international application No. PCT/CN2025/091537, filed on Apr. 27, 2025, which claims priority to Chinese Patent Application No. 202410608477.1, filed on May 16, 2024 and entitled “DISPLAY MODULE AND DISPLAY DEVICE”, the entire contents of which are incorporated herein by reference.

### TECHNICAL FIELD

The present disclosure relates to the field of display technologies, and in particular to a display module and a display device.

### BACKGROUND

With the continuous development of display technologies, the requirements on the safety performance during image display by display devices are becoming higher and higher. For example, a display module needs to achieve an anti-peeping function in certain privacy scenarios.

### SUMMARY

The present disclosure provides a display module and a display device. The technical solutions are as follows.

According to some embodiments of the present disclosure, a display module is provided. The display module includes:
a display panel, having an active face and a non-active face opposite to each other, the display panel including a plurality of light-emitting regions arranged at intervals, wherein the light-emitting regions are configured to emit light; and
a light-dimming assembly, disposed on the active face of the display panel and configured to modulate an angle of emergent light of the display panel, wherein the light-dimming assembly includes:
a first insulative layer, provided with openings, wherein the opening at least has a side wall, an orthographic projection of each of the openings on the display panel is disposed at a spacing between two adjacent light-emitting regions; and
a light-absorbing layer, including a light-absorbing structure, wherein the light-absorbing structure is arranged corresponding to the opening and configured to absorb light, the light-absorbing structure includes a first light-absorbing portion disposed in the corresponding opening and a second light-absorbing portion disposed on a side, away from the display panel, of the first insulative layer, the first light-absorbing portion is disposed in the opening, an orthographic projection of the second light-absorbing portion on the display panel at least surrounds an orthographic projection of the first light-absorbing portion on the display panel, the orthographic projection of the second light-absorbing portion on the display panel is not overlapped with the light-emitting region.

In some embodiments, a depth of the opening equals a thickness of the first insulative layer; and
a length of the first light-absorbing portion in a first direction equals the depth of the opening, a surface of the first light-absorbing portion is partially in contact with the active face of the display panel, and the first direction is perpendicular to the active face of the display panel.

In some embodiments, the orthographic projection of the second light-absorbing portion on the display panel covers the orthographic projection of the first light-absorbing portion on the display panel; and
a surface, away from the display panel, of the second light-absorbing portion is a planar surface.

In some embodiments, the orthographic projection of the second light-absorbing portion on the display panel covers the orthographic projection of the first light-absorbing portion on the display panel; and
a surface, away from the display panel, of the second light-absorbing portion is a non-planar surface, and a thickness of a portion, close to the opening, of the second light-absorbing portion is less than that of a portion, away from the opening, of the second light-absorbing portion.

In some embodiments, a surface, away from the display panel, of the second light-absorbing portion is recessed in a direction close to the display panel.

In some embodiments, the orthographic projection of the second light-absorbing portion on the display panel includes a first projection and a second projection, wherein the first projection is overlapped with a projection edge of the orthographic projection of the first light-absorbing portion on the display panel, the second projection surrounds the orthographic projection of the first light-absorbing portion on the display panel; and
the first light-absorbing portion has a first surface and a second surface opposite to each other, the first surface is close to the display panel relative to the second surface, the first surface is close to the side wall of the opening relative to the second surface, and a distance between the second surface and the active face of the display panel is less than a thickness of the first insulative layer.

In some embodiments, the opening further has a first side facing the display panel and a second side away from the display panel, the side wall of the opening connects the first side and the second side, an orthographic projection of the side wall on a first reference plane is a straight line, and the first reference plane is perpendicular to the active face of the display panel; and
an angle between the side wall and the first side and an angle between the side wall and the second side are complementary.

In some embodiments, the angle between the side wall and the first side is an acute angle, and the angle between the side wall and the second side is an obtuse angle; or
the angle between the side wall and the first side is an obtuse angle, and the angle between the side wall and the second side is an acute angle; or
the angle between the side wall and the first side and the angle between the side wall and the second side are right angles.

In some embodiments, the opening further has a first side facing the display panel and a second side away from the display panel, and the side wall of the opening connects the first side and the second side; and
an orthographic projection of the side wall on a first reference plane is an arc, the first reference plane is perpendicular to the active face of the display panel, and an end of the side wall close to the display panel is in smooth transition with the first side.

In some embodiments, the light-dimming assembly further includes a reflection structure; and
the reflection structure is disposed between the side wall of the opening and the first light-absorbing portion, and the orthographic projection of the second light-absorbing portion on the display panel covers an orthographic projection of the reflection structure on the display panel.

In some embodiments, a material of the reflection structure includes metal.

In some embodiments, a surface, away from the display panel, of the second light-absorbing portion has a first edge and a second edge, the first edge and the second edge are arranged in a second direction, the light-emitting region has a third edge and a fourth edge, the third edge and the fourth edge are arranged in the second direction, and the second direction is a direction in which the orthographic projection of the second light-absorbing portion on the display panel and the light-emitting region are arranged;
an angle α between a minimum connecting line between a first target edge of the second light-absorbing portion and a second target edge of a target light-emitting region, and a second reference plane ranges from 40 degrees to 60 degrees; and
the first target edge is one of the first edge and the second edge that is close to the target light-emitting region, the second target edge of the target light-emitting region is one of the third edge and the fourth edge that is away from the first target edge, and the second reference plane is parallel to the active face of the display panel.

In some embodiments, a distance d between the first target edge and the second target edge in the second direction meets:

$$d = h / tanα ;$$

wherein h is a distance between a surface, close to the light-dimming assembly, of an anode layer disposed in the light-emitting region of the display panel and a surface, away from the display panel, of the second light-absorbing portion in a first direction, and the first direction is perpendicular to the active face of the display panel.

In some embodiments, a thickness of the second light-absorbing portion is greater than 1 μm.

In some embodiments, the display module further includes: a second insulative layer, a lens layer and a third insulative layer that are disposed on a side, away from the display panel, of the light-dimming assembly and are sequentially stacked in a direction away from the display panel; and
a surface, away from the display panel, of the second insulative layer is a planar surface, the lens layer includes a plurality of lenses corresponding to the plurality of light-emitting regions, an orthographic projection of each of the lenses on the display panel covers the corresponding light-emitting region, and a refractive index of the lens is greater than that of the third insulative layer.

According to some embodiments of the present disclosure, a display device is provided. The display device includes a power supply assembly and a display module as described in the above embodiments; and
the power supply assembly is connected to the display module for supplying power to the display module.

### BRIEF DESCRIPTION OF DRAWINGS

In order to more clearly illustrate the technical solutions in the embodiments of the present disclosure, the drawings required for the descriptions of the embodiments will be briefly described below. Obviously, the drawings in the following description are only some embodiments of the present disclosure, and a person skilled in the art can obtain other drawings from the drawings without any inventive effort.

FIG. 1 is a schematic structural diagram of a display module in the related art;

FIG. 2 is a schematic structural diagram of another display module in the related art;

FIG. 3 is a schematic structural diagram of still another display module in the related art;

FIG. 4 is a schematic structural diagram of a display module according to some embodiments of the present disclosure;

FIG. 5 is a schematic structural diagram of another display module according to some embodiments of the present disclosure;

FIG. 6 is a schematic structural diagram of still another display module according to some embodiments of the present disclosure;

FIG. 7 is a schematic structural diagram of still another display module according to some embodiments of the present disclosure;

FIG. 8 is a schematic structural diagram of still another display module according to some embodiments of the present disclosure;

FIG. 9 is a schematic structural diagram of still another display module according to some embodiments of the present disclosure;

FIG. 10 is a schematic structural diagram of a display panel and a first insulative layer according to some embodiments of the present disclosure;

FIG. 11 is another schematic structural diagram of the display panel and the first insulative layer according to some embodiments of the present disclosure;

FIG. 12 is still another schematic structural diagram of the display panel and the first insulative layer according to some embodiments of the present disclosure;

FIG. 13 is still another schematic structural diagram of the display panel and the first insulative layer according to some embodiments of the present disclosure;

FIG. 14 is a schematic structural diagram of still another display module according to some embodiments of the present disclosure;

FIG. 15 is a schematic structural diagram of still another display module according to some embodiments of the present disclosure;

FIG. 16 is a schematic diagram of a partial structure of the display module shown in FIG. 15;

FIG. 17 is a top view of a light-emitting region and a second light-absorbing portion according to some embodiments of the present disclosure;

FIG. 18 is a schematic structural diagram of still another display module according to some embodiments of the present disclosure; and

FIG. 19 is a schematic structural diagram of a display panel according to some embodiments of the present disclosure.

### DETAILED DESCRIPTION

For clearer descriptions of the objectives, technical solutions, and advantages of the present disclosure, embodiments of the present disclosure are described in detail hereinafter with reference to the accompanying drawings.

In the related art, a display module includes a display panel and a light-absorbing assembly disposed on an active side of the display panel. The display panel includes a plurality of light-emitting regions arranged at intervals. In order to ensure the light absorption property of the light-absorbing assembly, the light-absorbing assembly at least includes a first light-absorbing layer, a planarization layer and a second light-absorbing layer along a side away from the display panel. Orthographic projections of the first light-absorbing layer and the second light-absorbing layer on the display panel are disposed at a spacing between the adjacent light-emitting regions. With this design, in the case that a display device displays images, large-viewing-angle light in light emitted from the light-emitting region is absorbed by the light-absorbing assembly, such that the display device can achieve an anti-peeping function, which can improve the safety performance of the display device.

However, due to a large number of film layers in the light-absorbing assembly, preparation process of the light-absorbing assembly is complicated, and the preparation efficiency is low.

For example, referring to FIG. 1, the display module includes a display panel and a light-absorbing assembly. The display panel includes a plurality of light-emitting regions arranged at intervals. Referring to FIG. 1, the light-absorbing assembly includes a first light-absorbing layer, a planarization layer and a second light-absorbing layer along a side away from the display panel.

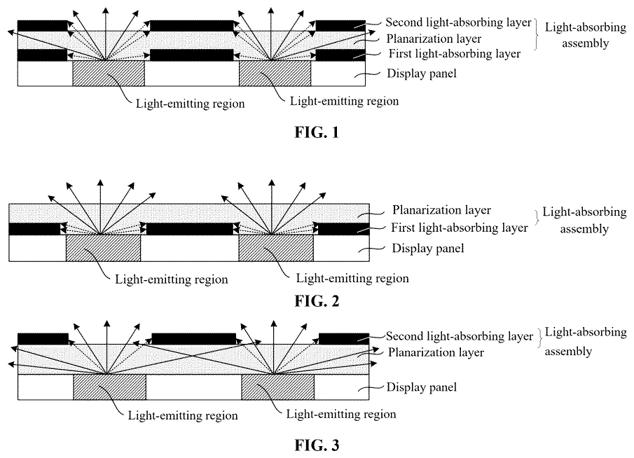

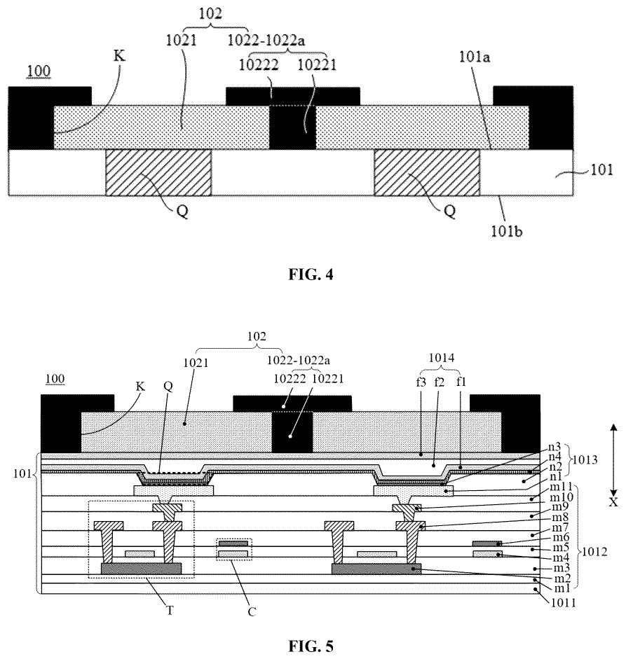

The reason for designing the two light-absorbing layers is as follows. In the case that only one light-absorbing layer is present, as shown in FIG. 2 and FIG. 3, the light-absorbing assembly cannot achieve a good light-absorbing effect on the large-viewing-angle light in the light emitted from the light-emitting region of the display panel. That is, in the case of only one light-absorbing layer, the display module cannot achieve a good anti-peeping function. In FIGS. 1 to 3, the solid lines are configured to represent emergent light, and the dotted lines are used to represent light absorbed.

Because the light-absorbing assembly includes two light-absorbing layers, and the two light-absorbing layers need to be prepared separately by two processes, the preparation process is complicated and the preparation efficiency is low.

FIG. 4 is a schematic structural diagram of a display module according to some embodiments of the present disclosure. Referring to FIG. 4, the display module 100 includes a display panel 101 and a light-dimming assembly 102.

The display panel 101 has an active face 101a and a non-active face 101b opposite to each other. The display panel 101 includes a plurality of light-emitting regions Q arranged at intervals, and the light-emitting regions Q are configured to emit light.

The light-dimming assembly 102 is disposed on the active face 101a of the display panel 101. The light-dimming assembly 102 is configured to modulate an angle of light emitted by the display panel 101. For example, the light-dimming assembly 102 is configured to absorb emergent light of some angles in light emitted from the light-emitting region Q of the display panel 101, which causes light finally emitted from the display module 100 to be light emitted from the light-emitting region Q but not absorbed by the light-dimming assembly 102, thereby achieving the function of modulating the angle of emergent light of the display panel 101.

Referring to FIG. 4, the light-dimming assembly 102 includes a first insulative layer 1021 and a light-absorbing layer 1022. The first insulative layer 1021 is provided with openings K. The opening K at least has a side wall, and an orthographic projection of the opening K on the display panel 101 is disposed at a spacing between two adjacent light-emitting regions Q. That is, the orthographic projection of the opening K on the display panel 101 is not overlapped with the light-emitting region Q.

The light-absorbing layer 1022 includes a light-absorbing structure 1022a, and the light-absorbing structure 1022a is arranged corresponding to the opening K. The light-absorbing structure 1022a is configured to absorb light. The light-absorbing structure 1022a includes a first light-absorbing portion 10221 disposed in the corresponding opening K and a second light-absorbing portion 10222 disposed on a side, away from the display panel 101, of the first insulative layer 1021. The first light-absorbing portion 10221 is disposed in the opening K to form a vertical shape.

Referring to FIG. 4, the first light-absorbing portion 10221 is disposed in the opening K, and an orthographic projection of the second light-absorbing portion 10222 on the display panel 101 at least surrounds an orthographic projection of the first light-absorbing portion 10221 on the display panel 101. Moreover, the orthographic projection of the second light-absorbing portion 10222 on the display panel 101 is not overlapped with the light-emitting region Q.

The orthographic projection of the second light-absorbing portion 10222 on the display panel 101 at least surrounds the orthographic projection of the first light-absorbing portion 10221 on the display panel 101, which indicates that the orthographic projection of the second light-absorbing portion 10222 on the display panel 101 includes a portion of projection that is overlapped with the orthographic projection of the first light-absorbing portion 10221 on the display panel 101 and another portion of projection that surrounds the orthographic projection of the first light-absorbing portion 10221 on the display panel 101.

For example, referring to FIG. 4, the orthographic projection of the second light-absorbing portion 10222 on the display panel 101 covers the orthographic projection of the first light-absorbing portion 10221 on the display panel 101 (which is intended to represent overlapping), and the orthographic projection of the second light-absorbing portion 10222 on the display panel 101 has a part that extends beyond the orthographic projection of the first light-absorbing portion 10221 on the display panel 101 (which is intended to represent surrounding).

Further, because the orthographic projection of the second light-absorbing portion 10222 on the display panel 101 is not overlapped with the light-emitting region Q, in the light emitted from the light-emitting region Q, the light that is emergent in a substantially normal direction (light with a small viewing angle) is not absorbed by the second light-absorbing portion 10222, thereby avoiding any impact on normal display of the display module 100.

In the embodiments of the present disclosure, because the first insulative layer 1021 is provided with the openings K, the first light-absorbing portion 10221 of the light-absorbing structure 1022a is disposed in the opening K, and the second light-absorbing portion 10222 of the light-absorbing structure 1022a is disposed on the side, away from the display panel 101, of the first insulative layer 1021. In the light emitted from the light-emitting region Q, the light that is irradiated onto the second light-absorbing portion 10222 can be absorbed by the second light-absorbing portion 10222, and the light that is irradiated onto the first light-absorbing portion 10221 can be absorbed by the first light-absorbing portion 10221. This expands the range of angle of the light that can be absorbed. That is, the light-absorbing structure 1022a is enabled to achieve a good light-absorbing effect on the light emitted from the light-emitting region Q, and the display module 100 is enabled to have a good anti-peeping function. According to the solution of the embodiments of the present disclosure, it is unnecessary to design multiple light-absorbing layers 1022 to absorb light, which can simplify the preparation process and improve the preparation efficiency of the light-dimming assembly 102.

For example, referring to FIG. 1, the display module is provided with two light-absorbing layers, during preparation, the two light-absorbing layers need to be prepared by two processes. However, in the solution of the present disclosure, referring to FIG. 4, the light-absorbing structure 1022a in the light-absorbing layer 1022 can be formed only by adopting a one-time process upon designing the opening K in the first insulative layer 1021. That is, compared with the solution in the prior art, the embodiments of the present disclosure can save at least one preparation process.

In summary, the embodiments of the present disclosure provide a display module. The display module includes a display panel and a light-dimming assembly disposed on an active face of the display panel. The first insulative layer in the light-dimming assembly is provided with openings, and a light-absorbing structure of a light-absorbing layer in the light-dimming layer has a first light-absorbing portion disposed in the opening and a second light-absorbing portion disposed on a side, away from the display panel, of the first insulative layer. The light-dimming assembly can absorb large-viewing-angle light in light emitted from a light-emitting region of the display panel, such that the display module has an anti-peeping function. Moreover, in the light-dimming assembly according to the embodiments of the present disclosure, the light-absorbing layer is prepared only by adopting a one-time process in the case that the preparation of the first insulative layer is completed, thereby simplifying the preparation process and improving the preparation efficiency.

Optionally, the first insulative layer 1021 is provided with a plurality of openings K. The light-absorbing layer 1022 includes a plurality of light-absorbing structures 1022a, and the plurality of light-absorbing structures 1022a are arranged corresponding to the plurality of openings K. The first light-absorbing portion 10221 of the light-absorbing structure 1022a is disposed in the corresponding opening K.

Optionally, the display panel 101 is a low temperature poly-silicon (LTPS) display panel. Alternatively, the display panel 101 is a low temperature polycrystalline oxide (LTPO) display panel.

In some embodiments of the present disclosure, the display panel 101 includes a plurality of pixel units, and each of the plurality of pixel units includes a plurality of sub-pixels. Each of the plurality of sub-pixels includes a driving circuit and a light-emitting unit. Optionally, the plurality of sub-pixels in each of the plurality of pixel units include a red sub-pixel (red, R), a green sub-pixel (green, G) and a blue sub-pixel (blue, B).

Optionally, the driving circuit includes a plurality of thin film transistors (TFTs) and at least one storage capacitor. For example, the driving circuit includes 7 thin film transistors and 1 storage capacitor, i.e., the driving circuit is a 7T1C driving circuit. Alternatively, the driving circuit includes another number of thin film transistors and another number of storage capacitors. The number of neither the thin film transistors nor the storage capacitors in the driving circuit is limited in the embodiments of the present disclosure.

The LTPS display panel means that all the thin film transistors in the display panel 101 are LTPS transistors. The LTPO display panel means that at least one thin film transistor in the display panel 101 is an LTPO transistor.

Each of the plurality of thin film transistors includes a gate, a source and a drain. The plurality of thin film transistors in the driving circuit are connected with each other to achieve the function of driving the light-emitting unit to emit light.

FIG. 5 is a schematic structural diagram of another display module according to some embodiments of the present disclosure. Referring to FIG. 5, the display panel 101 includes a base substrate 1011, and a driving circuit layer 1012, a light-emitting unit layer 1013 and an encapsulation film layer 1014 that are disposed and stacked on the base substrate 1011. The driving circuit layer 1012 includes driving circuits of a plurality of sub-pixels, and the light-emitting unit layer 1013 includes light-emitting units of a plurality of sub-pixels.

Referring to FIG. 5, the driving circuit layer 1012 includes a buffer layer m1, a semiconductor layer m2, a first gate insulator (GI) layer m3, a first gate layer m4, a second gate insulator layer m5, a second gate layer m6, an inter layer dielectric (ILD) layer m7, a first source-drain (SD1) layer m8, a first planarization (PLN) layer m9, a second source-drain (SD2) layer m10 and a second planarization layer m11 that are sequentially stacked in a direction away from the base substrate 1011. The light-emitting unit layer 1013 includes an anode layer n1, a pixel definition layer (PDL) n2, a light-emitting layer n3 and a cathode layer n4 that are sequentially stacked in a direction away from the base substrate 1011.

The semiconductor layer m2 includes a plurality of semiconductor patterns corresponding to a plurality of thin film transistors T, and each semiconductor pattern includes a source region, a drain region and a channel region. Sources and drains of the thin film transistors T are disposed in the first source-drain layer m8, and the thin film transistors have the sources connected to the source region, and the drains connected to the drain region.

The first gate layer m4 includes a plurality of gate patterns corresponding to the plurality of thin film transistors T. The channel region is a region where orthographic projections of the gate patterns on the base substrate 1011 are overlapped with orthographic projections of the semiconductor patterns on the base substrate 1011. In addition, the first gate layer m4 further includes a first polar plate of a storage capacitor C, and the second gate layer m6 includes a second polar plate of the storage capacitor C.

The second source-drain layer m10 includes a plurality of connection patterns, and each connection pattern is connected to the drain of the thin film transistor and an anode pattern of the anode layer n1.

The anode layer n1 includes a plurality of anode patterns, and each of the plurality of anode patterns is used as an anode of one light-emitting unit. The pixel definition layer n2 has a plurality of hollowed-out regions, and each hollowed-out region is configured to expose one anode pattern. The light-emitting layer n3 includes a plurality of light-emitting patterns, each light-emitting pattern is connected to the anode pattern through one hollowed-out region, and each light-emitting pattern is used as a light-emitting portion of one light-emitting unit. The cathode layer n4 is an entire film layer and is connected to the light-emitting portions of the plurality of light-emitting units.

The encapsulation film layer 1014 includes a first film layer f1, a second film layer f2 and a third film layer f3 that are stacked in a direction away from the base substrate 1011.

Optionally, the first film f1 and the third film f3 is made from inorganic materials, and the second film f2 is made from an organic material. For example, the first film f1 and the third film f3 is made from one or more inorganic oxides such as SiNx (silicon nitride), SiOx (silicon oxide) and SiOxNy (silicon oxynitride). The second film layer f2 is made of resin. The resin is thermoplastic resin or thermosetting resin, the thermoplastic resin includes polymethyl methacrylate (PMMA) resin, and the thermosetting resin includes epoxy resin.

In some embodiments of the present disclosure, the second film f2 is made by means of ink jet printing (IJP). The first film f1 and the third film f3 is made by means of chemical vapor deposition (CVD).

In some embodiments of the present disclosure, the active face 101a of the display panel 101 refers to a surface, close to the light-dimming assembly 102, of one film layer that is closest to the light-dimming assembly 102 among all the film layers in the display panel 101. The non-active face 101b of the display panel 101 refers to a surface, away from the light-dimming assembly 102, of one film layer that is farthest from the light-dimming assembly 102 among all the film layers in the display panel 101.

In an exemplary embodiment, for the display panel 101 shown in FIG. 5, the active face 101a of the display panel 101 is a surface, close to the light-dimming assembly 102, of the third film f3, and the non-active face 101b of the display panel 101 is a surface, away from the light-dimming assembly 102, of the base substrate 1011.

In some embodiments of the present disclosure, referring to FIGS. 4 and 5, the depth of the opening K equals the thickness of the first insulative layer 1021. The length of the first light-absorbing portion 10221 in a first direction X equals the depth of the opening K. The surface of the first light-absorbing portion 10221 is partially in contact with the active face 101a of the display panel 101. For example, in FIG. 4, a surface, close to the display panel 101, of the first light-absorbing portion 10221 is in contact with the active face 101a of the display panel 101. The first direction X is perpendicular to the active face 101a of the display panel 101.

Because the depth of the opening K equals the thickness of the first insulative layer 1021, the opening K in the first insulative layer 1021 is an opening running through the first insulative layer 1021. In this way, the first light-absorbing portion 10221 disposed in the opening K can be made as long as possible in the first direction X, such that the light emitted from the light-emitting region Q of the display panel 101 can be absorbed by the first light-absorbing portion 10221 within the whole range of thickness of the first insulative layer 1021, thereby ensuring the light-absorbing effect of the light-absorbing structure 1022a on the large-viewing-angle light and improving the anti-peeping effect of the display module.

During preparation of the light-absorbing layer 1022, a side, away from the display panel 101, of the first insulative layer 1021 is coated with a light-absorbing material, and then the light-absorbing material is patterned with a mask. In the process of applying the light-absorbing material, the light-absorbing material preferentially flows to a lower-lying position under the action of gravity. Because the first insulative layer 1021 is provided with the opening K, and the opening K is lower than other regions, the light-absorbing material preferentially flows to the opening K.

In the case where sufficient light-absorbing material is applied, the light-absorbing material is leveled at the opening K and other regions. Thus, referring to FIGS. 4 to 6, an orthographic projection of the second light-absorbing portion 10222 on the display panel 101 covers an orthographic projection of the first light-absorbing portion 10221 on the display panel 101. A surface, away from the display panel 101, of the second light-absorbing portion 10222 is a planar surface.

In the case where less light-absorbing material is applied, the light-absorbing material preferentially flows to the opening K, which probably cannot ensure that the light-absorbing material is leveled at the opening K and other regions. Thus, referring to FIGS. 7 and 8, an orthographic projection of the second light-absorbing portion 10222 on the display panel 101 covers an orthographic projection of the first light-absorbing portion 10221 on the display panel 101. A surface, away from the display panel 101, of the second light-absorbing portion 10222 is a non-planar surface. In addition, the thickness of a portion of the second light-absorbing portion 10222 close to the opening K is less than that of a portion of the second light-absorbing portion 10222 away from the opening K.

Optionally, referring to FIGS. 7 and 8, the surface, away from the display panel 101, of the second light-absorbing portion 10222 is recessed in a direction close to the display panel 101. For example, the surface, away from the display panel 101, of the second light-absorbing portion 10222 is a recessed arc surface.

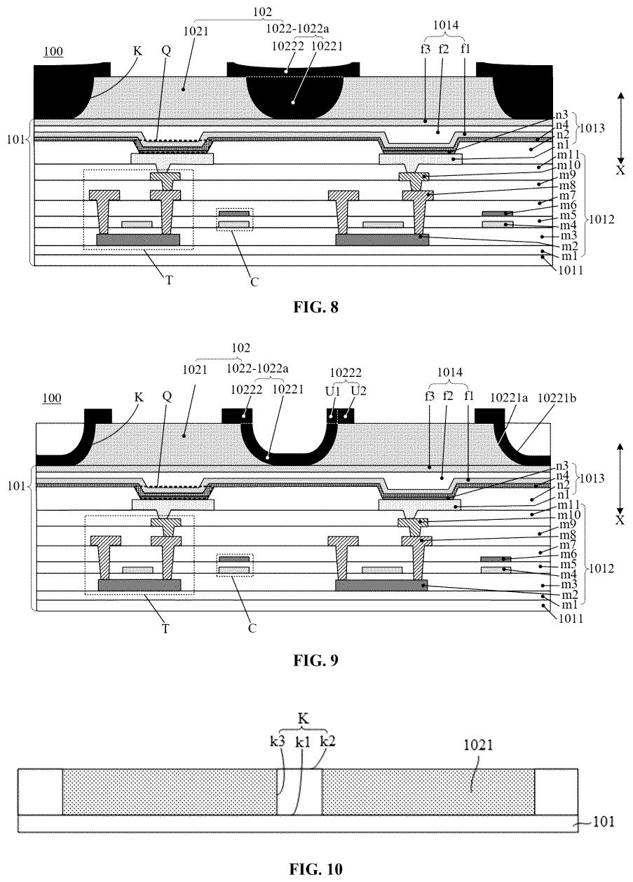

In some embodiments of the present disclosure, referring to FIG. 9, the second light-absorbing portion 10222 is of an annular structure. The orthographic projection of the second light-absorbing portion 10222 on the display panel 101 includes a first projection U1 and a second projection U2. The first projection U1 is overlapped with an objection edge of the orthographic projection of the first light-absorbing portion 10221 on the display panel 101, and the second projection U2 surrounds the orthographic projection of the first light-absorbing portion 10221 on the display panel 101.

The first light-absorbing portion 10221a has a first surface 10221a and a second surface 10221b opposite to each other. The first surface 10221a is close to the display panel 101 relative to the second surface 10221b, and the first surface 10221a is close to the side wall of the opening K relative to the second surface 10221b. The distance between the second surface 10221b and the active face 101a of the display panel 101 is less than the thickness of the first insulative layer 1021.

That is, in the solution shown in FIG. 9, the second surface 10221b of the first light-absorbing portion 10221 is closer to the display panel than the surface, away from the display panel 101, of the first insulative layer 1021. The structure shown in FIG. 9 is formed during preparation of the light-absorbing layer 1022, where the light-absorbing material preferentially flows to the opening K due to less application of the light-absorbing material.

In some embodiments of the present disclosure, referring to FIGS. 10 to 12, the opening K also has a first side k1 facing the display panel 101 and a second side k2 away from the display panel 101, a side wall k3 of the opening K connects the first side k1 and the second side k2, an orthographic projection of the side wall k3 on a first reference plane is a straight line, and the first reference plane is perpendicular to the active face 101a of the display panel 101.

An angle between the side wall k3 and the first side k1 and an angle between the side wall k3 and the second side k2 are complementary. That is, the sum of the angle between the side wall k3 and the first side k1 and the angle between the side wall k3 and the second side k2 is 180 degrees.

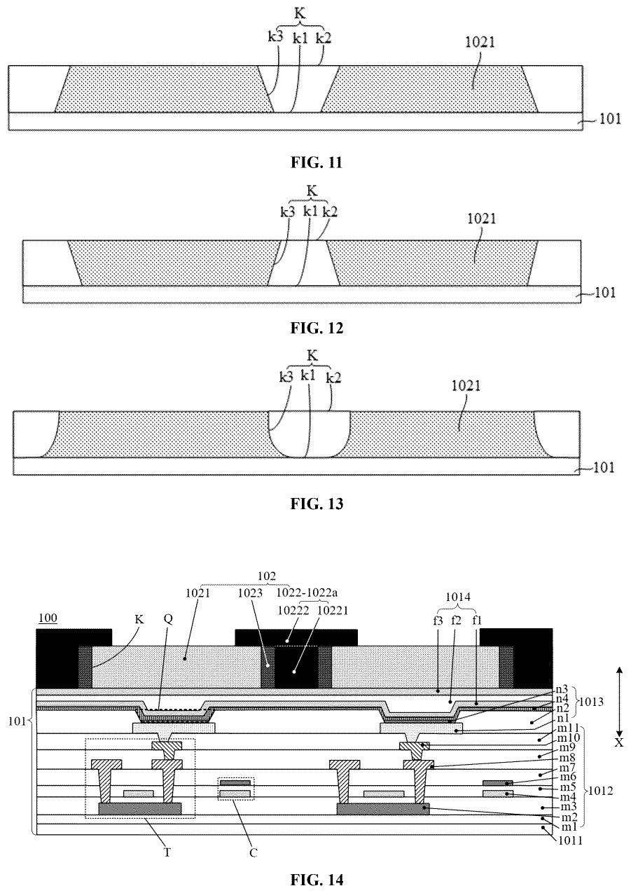

Optionally, referring to FIG. 12, the angle between the side wall k3 and the first side k1 is an acute angle, and the angle between the side wall k3 and the second side k2 is an obtuse angle. That is, an orthographic projection of the opening K on the first reference plane is in the shape of an inverted trapezoid.

Alternatively, referring to FIG. 11, the angle between the side wall k3 and the first side k1 is an obtuse angle, and the angle between the side wall k3 and the second side k2 is an acute angle. That is, an orthographic projection of the opening K on the first reference plane is in the shape of a regular trapezoid.

Alternatively, referring to FIG. 10, the angle between the side wall k3 and the first side k1 and the angle between the side wall k1 and the second side k2 are right angles. That is, an orthographic projection of the opening K on the first reference plane is rectangular. The opening K shown in FIG. 10 is the opening applied in the above FIGS. 4, 5 and 7.

It should be noted that the orthographic projection of the opening K on the display panel 101 is in the shape of a circle, a rectangle, a regular polygon and the like. The shape of the orthographic projection of the opening K on the display panel 101 will not be specifically limited in the embodiments of the present disclosure.

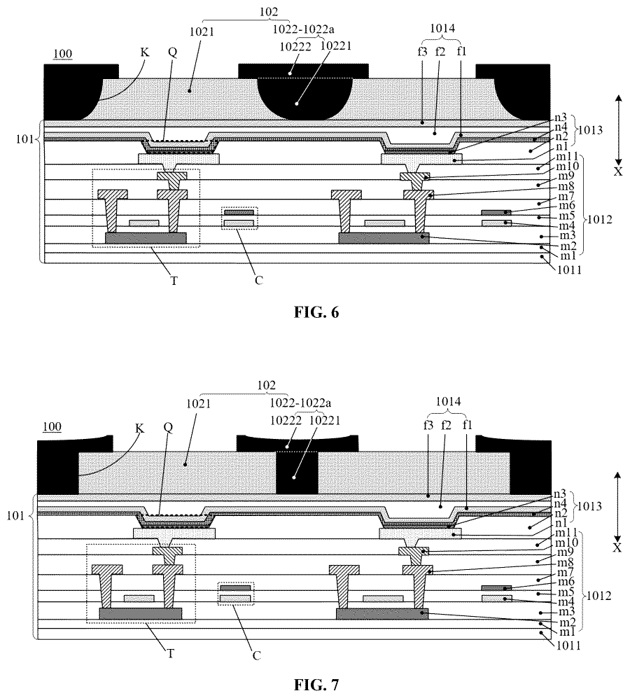

In some embodiments of the present disclosure, referring to FIG. 13, the opening K also has a first side k1 facing the display panel 101 and a second side k2 away from the display panel 101. The side wall k3 of the opening K connects the first side k1 and the second side k2. The orthographic projection of the side wall k3 on a first reference plane is an arc. The end of the side wall k3 close to the display panel 101 is in smooth transition with the first side k1. The opening K shown in FIG. 13 is the opening applied in the above FIGS. 6, 8 and 9.

Optionally, the material of the first insulative layer 1021 is an organic material, and during formation of the opening K, an inward-bending shape is formed. The concave opening as shown in 13 is formed in the case that the opening K is of a small size. In an exemplary embodiment, in the case that a width of the orthographic projection of the designed opening K on the display panel 101 is less than 5 μm (micron), the opening K is a concave opening as shown in FIG. 13.

In some embodiments of the present disclosure, because the light-dimming assembly 102 absorbs the large-viewing-angle light in the light emitted from the light-emitting region Q, only a portion of the light emitted from the light-emitting region Q is emergent, resulting in low brightness of the display module.

In order to solve the above problem, referring to FIGS. 14 and 15, the light-dimming assembly 102 further includes a reflection structure 1023. The reflection structure 1023 is disposed between the side wall of the opening K and the first light-absorbing portion 10221, and the orthographic projection of the second light-absorbing portion 10222 on the display panel 101 covers an orthographic projection of the reflection structure 1023 on the display panel 101.

In the light emitted from the light-emitting region Q, a portion of the light irradiated onto the reflection structure 1023 is reflected by the reflection structure 1023, a portion of the light reflected by the reflection structure 1023 is absorbed by the second light-absorbing portion 10222 simultaneously, and the other portion of the light is emergent from the light-emitting region Q. That is, a portion of the large-viewing-angle light in the light emitted from the light-emitting region Q is reflected to the light-emitting region Q and thus emergent, which in turn can improve the luminous brightness of the display module 100 without increasing the power consumption of the display module 100.

Optionally, the material of the reflection structure 1023 includes metal. The metal usually has good reflective property, so setting the material of the reflection structure 1023 as the metal can provide better reflection of light. In an exemplary embodiment, the material of the reflection structure 1023 is of a three-layer structure of titanium (Ti), aluminum (Al) and titanium (Ti).

Optionally, the reflection structure 1023 is prepared using an ion sputtering process. During the preparation, it can be ensured that the reflection structure 1023 is ion-sputtered according to the bottom shape of the opening K. Generally, the angle β between the side wall k3 of the opening K and the surface, close to the display panel 101, of the first insulative layer 1021 ranges from 70 degrees to 90 degrees. Moreover, in the case where the angle between the side wall k3 of the opening K and the surface, close to the display panel 101, of the first insulative layer 1021 is 90 degrees, anti-peeping and front light-emergent effects can be better achieved. Moreover, it should be noted that the reflection structure 1023 can be subjected to 90-degree ion sputtering coating in terms of process preparation.

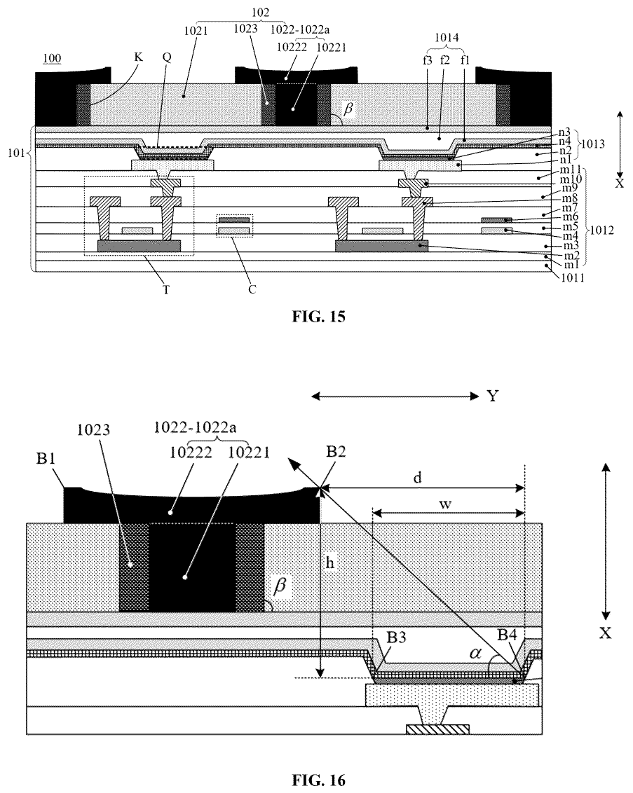

FIG. 16 is a schematic diagram of a partial structure of FIG. 15. Referring to FIG. 16, a surface, away from the display panel 101, of the second light-absorbing portion 10222 has a first edge B1 and a second edge B2, and the first edge B1 and the second edge B2 are arranged in a second direction Y. The light-emitting region Q has a third edge B3 and a fourth edge B4, and the third edge B3 and the fourth edge B4 are arranged in the second direction Y. The second direction Y is a direction in which the orthographic projection of the second light-absorbing portion 10222 on the display panel 101 and the light-emitting region Q are arranged.

An angle α between a minimum connecting line between a first target edge Bm1 of the second light-absorbing portion 10222 and a second target edge Bm2 of a target light-emitting region Q, and a second reference plane ranges from 40 degrees to 60 degrees.

The first target edge Bm1 is one of the first edge B1 and the second edge B2 that is close to the target light-emitting region Q. The second target edge Bm2 of the target light-emitting region Q is one of the third edge B3 and the fourth edge B4 that is away from the first target edge Bm1. The second reference plane is parallel to the active face 101a of the display panel 101. In FIG. 6, the second edge B2 is the first target edge Bm1, and the fourth edge B4 is a second target edge Bm2.

As can be seen from FIG. 16, the light emitted from the light-emitting region Q, being of an angle smaller than the angle α, is irradiated onto the light-absorbing structure 1022a and thus absorbed, or irradiated onto the reflection structure 1023 and thus reflected. The light emitted from the light-emitting region Q, being of an angle greater than the angle α, is directly emergent.

Referring to FIG. 16, a distance d between the first target edge Bm1 and the second target edge Bm2 in the second direction Y meets:

$$d = h / tanα , \qquad Formula ( 1 )$$

where h is a distance between a surface, close to the light-dimming assembly 102, of an anode layer n1 disposed in the light-emitting region Q of the display panel 101 and the surface, away from the display panel 101, of the second light-absorbing portion 10222 in the first direction X. The first direction X is perpendicular to the active face 101a of the display panel 101a. That is, h is the sum of the total thickness of all the film layers in the display panel 101 disposed on the side, close to the light-dimming assembly 102, of the anode layer n1 in the light-emitting region Q, and the total thickness of the first insulative layer 1021 and the second light-absorbing portion 10222 of the light-dimming assembly 102.

In addition, the distance d between the first target edge Bm1 and the second target edge Bm2 in the second direction Y also refers to a maximum distance between one side of the light-emitting region Q and an edge of the second light-absorbing portion 10222 on an opposite side. In addition, it should be noted that the length of the light-emitting region Q in the second direction Y is w, and the difference (d−w) between the distance d and the length w refers to a distance between the second light-absorbing portion 10222 and the light-emitting region Q in the second direction Y. In order to prevent the second light-absorbing portion 10222 from affecting the light-emitting region Q, it is necessary to make the difference between the distance d and the length w greater than or equal to 0.

Due to the process, there are some errors in the distance d, the distance h and the angle α in the case that the preparation is completed. In some embodiments of the present disclosure, the errors of the distance d, the distance h and the angle α should be within 5%, which can also be considered as conforming to the relationship of the above formula (1).

In addition, because the light-emitting regions Q of different products are of different sizes, and sub-pixels of different colors (such as a red sub-pixel R, a green sub-pixel G and a blue sub-pixel B) are also of different sizes, the specific parameter range of the distance d or of the distance h is not provided in the present disclosure.

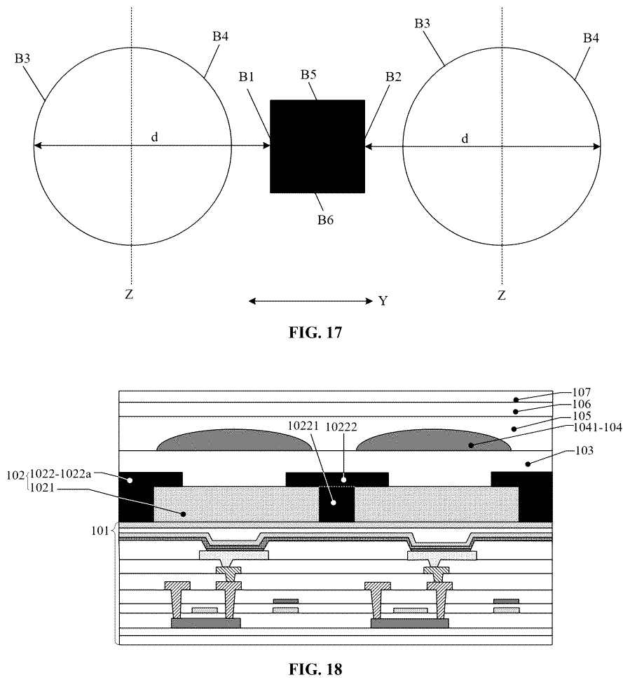

Referring to FIG. 17, assuming that the orthographic projection of the second light-absorbing portion 10222 on the display panel 101 is rectangular, the second light-absorbing portion 10222 has two other edges (B5 and B6) in addition to the first edge B1 and the second edge B2, and a direction in which these two edges (B5 and B6) extend is the second direction Y. Assuming that the light-emitting region Q is circular, the first edge B1 and the second edge B2 of the light-emitting region Q are two arc edges divided by a target axis Z (the target axis Z is perpendicular to the second direction Y) as a central axis. In this case, the distance d between the first target edge Bm1 and the second target edge Bm2 in the second direction Y refers to the maximum distance between the first target edge Bm1 and the second target edge Bm2 in the second direction Y.

In some embodiments of the present disclosure, a thickness of the second light-absorbing portion 10222 is greater than 1 μm (micron). Such a design can make the second light-absorbing portion 10222 to meet the requirement for a transmittance of less than one thousandth. The thickness of the second light-absorbing portion 10222 refers to the maximum thickness of the thicknesses of different regions of the second light-absorbing portion 10222.

FIG. 18 is a schematic structural diagram of still another display module according to some embodiments of the present disclosure. Referring to FIG. 18, the display module 100 further includes a second insulative layer 103, a lens layer 104 and a third insulative layer 105 that are disposed on a side, away from the display panel 101, of the light-dimming assembly 102 and sequentially stacked in a direction away from the display panel 101.

The surface, away from the display panel 101, of the second insulative layer 103 is a planar surface. That is, the second insulative layer 103 can play a role of planarization. The lens layer 104 includes a plurality of lenses 1041 corresponding to the plurality of light-emitting regions Q, and an orthographic projection of each lens 1041 on the display panel 101 covers the corresponding light-emitting region Q. The refractive index of the lens 1041 is greater than that of the third insulative layer 105. In an exemplary embodiment, the refractive index of the lens 1041 ranges from 1.6 to 1.8, and the refractive index of the third insulative layer 105 is less than 1.5.

In some embodiments of the present disclosure, the light emergent from the display panel 101 is irradiated into the lens, and is refracted at an interface between the lens 1041 and the third insulative layer 105, achieving convergence of light, such that the light is collected in a small-viewing-angle direction and then emergent. In addition, a surface, away from the display panel 101, of the third insulative layer 105 is also a planar surface.

Further, referring to FIG. 18, the display module 100 further includes a polarizer (pol) layer 106 and a cover 107. The polarizer layer 106 is disposed on a side, away from the display panel 101, of the third insulative layer 105, and the cover 107 is disposed on a side, away from the display panel 101, of the polarizer layer 106. The cover 107 is a glass cover.

In some embodiments of the present disclosure, the base substrate 1011 in the display panel 101 is a rigid substrate or a flexible substrate. In an exemplary embodiment, the material of the base substrate 1011 is glass, or the material of the base substrate 1011 is polyimide (PI).

Both of the first insulative layer 1021 and the second insulative layer 103 is over coatings (OC). The material of the light-absorbing structure 1022a is a black light-blocking material, which for example is called a black matrix (BM).

In summary, the embodiments of the present disclosure provide a display module. The display module includes a display panel and a light-dimming assembly disposed on an active face of the display panel. The first insulative layer in the light-dimming assembly is provided with an opening, and a light-absorbing structure of a light-absorbing layer in the light-dimming layer has a first light-absorbing portion disposed in the opening and a second light-absorbing portion disposed on a side, away from the display panel, of the first insulative layer. The light-dimming assembly can absorb large-viewing-angle light in light emitted from a light-emitting region of the display panel, such that the display module has an anti-peeping function. Moreover, according to the light-dimming assembly provided by the embodiments of the present disclosure, the light-absorbing layer is prepared only by adopting a one-time process in the case that the preparation of the first insulative layer is completed, thereby simplifying the preparation process and improving the preparation efficiency.

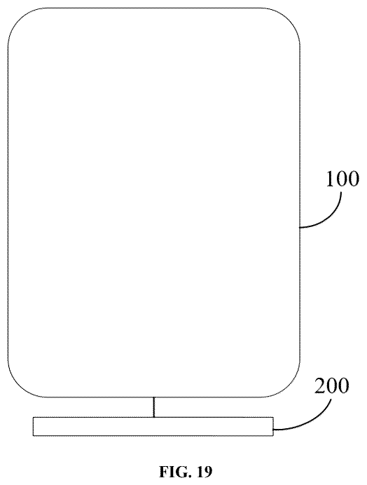

FIG. 19 is a schematic structural diagram of a display device according to some embodiments of the present disclosure. Referring to FIG. 19, the display device includes a power supply assembly 200 and a display module 100 as provided in the above embodiments. The power supply assembly 200 is connected to the display module 100 for supplying power to the display module 100.

Optionally, the display panel is an organic light-emitting diode (OLED) display panel, and then the display device is an OLED display device. In an exemplary embodiment, the display panel is an active-matrix organic light-emitting diode (AMOLED) display panel, and then the display device is an AMOLED display device.

Optionally, the display device is any suitable display device, including but not limited to a mobile phone, a tablet computer, a television, a monitor, a notebook computer, a digital photo frame, a vehicle navigator, an e-book and any other product or component having a display function.

In the embodiment of the present disclosure, because a vehicle-mounted product demands more on the anti-peeping performance than other products, the display device provided by the embodiment of the present disclosure is used in a vehicle, i.e., the display device is a vehicle-mounted display device.

The display device is applied to a vehicle, i.e., the display device is a vehicle-mounted display device.

Because the display device has substantially the same technical effects as the display module described in the previous embodiments, for the sake of brevity, the technical effects of the display device will not be repeated herein.

The terms used in the embodiments of the present disclosure are used only for the purpose of explaining the embodiments of the present disclosure but not intended to limit the present disclosure. Unless otherwise defined, the technical terms or scientific terms used in the embodiments of the present disclosure shall be taken to mean the ordinary meanings as understood by those of ordinary skill in the art to which the present disclosure belongs.

The terms “first”, “second”, “third” and the like used in the Description and Claims of the present disclosure do not denote any order, quantity, or importance, but are merely used to distinguish different components. Similarly, the terms “one”, “a” and the like are not intended to limit the number, but to denote the number of at least one. The terms “comprise”, “include” and the like are intended to mean that the elements or objects before said term cover the elements or objects or equivalents listed after said term, without excluding other elements or objects. The terms “connect”, “connected to” and the like are not limited to physical or mechanical connections, and may include electrical connection and the connection may be direct or indirect. The terms “upper”, “lower”, “left”, “right” and the like are only used to indicate the relative positional relationship, and when the absolute position of a described object changes, the relative positional relationship may also change accordingly.

Described above are only the optional embodiments of the present disclosure but not intended to limit the present disclosure. Any modifications, equivalent substitutions, improvements, etc., made within the spirit and principles of the present disclosure should be included within the scope of protection of the present disclosure.

1. A display module, comprising:
a display panel, having an active face and a non-active face opposite to each other, the display panel comprising a plurality of light-emitting regions arranged at intervals, wherein the light-emitting regions are configured to emit light; and
a light-dimming assembly, disposed on the active face of the display panel and configured to modulate an angle of emergent light of the display panel, wherein the light-dimming assembly comprises:
a first insulative layer, provided with openings, wherein the opening at least has a side wall, an orthographic projection of each of the openings on the display panel is disposed at a spacing between two adjacent light-emitting regions; and
a light-absorbing layer, comprising a light-absorbing structure, wherein the light-absorbing structure is arranged corresponding to the opening and configured to absorb light, the light-absorbing structure comprises a first light-absorbing portion disposed in the corresponding opening and a second light-absorbing portion disposed on a side, away from the display panel, of the first insulative layer, the first light-absorbing portion is disposed in the opening, an orthographic projection of the second light-absorbing portion on the display panel at least surrounds an orthographic projection of the first light-absorbing portion on the display panel, and the orthographic projection of the second light-absorbing portion on the display panel is not overlapped with the light-emitting region.

2. The display module according to claim 1, wherein a depth of the opening equals a thickness of the first insulative layer; and
a length of the first light-absorbing portion in a first direction equals the depth of the opening, a surface of the first light-absorbing portion is partially in contact with the active face of the display panel, and the first direction is perpendicular to the active face of the display panel.

3. The display module according to claim 1, wherein the orthographic projection of the second light-absorbing portion on the display panel covers the orthographic projection of the first light-absorbing portion on the display panel; and
a surface, away from the display panel, of the second light-absorbing portion is a planar surface.

4. The display module according to claim 1, wherein the orthographic projection of the second light-absorbing portion on the display panel covers the orthographic projection of the first light-absorbing portion on the display panel; and
a surface, away from the display panel, of the second light-absorbing portion is a non-planar surface, and a thickness of a portion, close to the opening, of the second light-absorbing portion is less than that of a portion, away from the opening, of the second light-absorbing portion.

5. The display module according to claim 4, wherein the surface, away from the display panel, of the second light-absorbing portion is recessed in a direction close to the display panel.

6. The display module according to claim 1, wherein the orthographic projection of the second light-absorbing portion on the display panel comprises a first projection and a second projection, wherein the first projection is overlapped with a projection edge of the orthographic projection of the first light-absorbing portion on the display panel, the second projection surrounds the orthographic projection of the first light-absorbing portion on the display panel; and
the first light-absorbing portion has a first surface and a second surface opposite to each other, the first surface is close to the display panel relative to the second surface, the first surface is close to the side wall of the opening relative to the second surface, and a distance between the second surface and the active face of the display panel is less than a thickness of the first insulative layer.

7. The display module according to claim 1, wherein the opening further has a first side facing the display panel and a second side away from the display panel, the side wall of the opening connects the first side and the second side, an orthographic projection of the side wall on a first reference plane is a straight line, and the first reference plane is perpendicular to the active face of the display panel; and
an angle between the side wall and the first side and an angle between the side wall and the second side are complementary.

8. The display module according to claim 7, wherein the angle between the side wall and the first side is an acute angle, and the angle between the side wall and the second side is an obtuse angle; or
the angle between the side wall and the first side is an obtuse angle, and the angle between the side wall and the second side is an acute angle; or
the angle between the side wall and the first side and the angle between the side wall and the second side are right angles.

9. The display module according to claim 1, wherein the opening further has a first side facing the display panel and a second side away from the display panel, and the side wall of the opening connects the first side and the second side; and
an orthographic projection of the side wall on a first reference plane is an arc, the first reference plane is perpendicular to the active face of the display panel, and an end of the side wall close to the display panel is in smooth transition with the first side.

10. The display module according to claim 1, wherein the light-dimming assembly further comprises a reflection structure; and
the reflection structure is disposed between the side wall of the opening and the first light-absorbing portion, and the orthographic projection of the second light-absorbing portion on the display panel covers an orthographic projection of the reflection structure on the display panel.

11. The display module according to claim 10, wherein a material of the reflection structure comprises metal.

12. The display module according to claim 1, wherein a surface, away from the display panel, of the second light-absorbing portion has a first edge and a second edge, the first edge and the second edge are arranged in a second direction, the light-emitting region has a third edge and a fourth edge, the third edge and the fourth edge are arranged in the second direction, and the second direction is a direction in which the orthographic projection of the second light-absorbing portion on the display panel and the light-emitting region are arranged;
an angle α between a minimum connecting line between a first target edge of the second light-absorbing portion and a second target edge of a target light-emitting region and a second reference plane ranges from 40 degrees to 60 degrees; and
the first target edge is one of the first edge and the second edge that is close to the target light-emitting region, the second target edge of the target light-emitting region is one of the third edge and the fourth edge that is away from the first target edge, and the second reference plane is parallel to the active face of the display panel.

13. The display module according to claim 12, wherein a distance d between the first target edge and the second target edge in the second direction meets:
$$d = h / tan α ;$$
wherein h is a distance between a surface, close to the light-dimming assembly, of an anode layer disposed in the light-emitting region of the display panel and a surface, away from the display panel, of the second light-absorbing portion in a first direction, and the first direction is perpendicular to the active face of the display panel.

14. The display module according to claim 1, wherein a thickness of the second light-absorbing portion is greater than 1 μm.

15. The display module according to claim 1, further comprising: a second insulative layer, a lens layer and a third insulative layer that are disposed on a side, away from the display panel, of the light-dimming assembly and are sequentially stacked in a direction away from the display panel; and
a surface, away from the display panel, of the second insulative layer is a planar surface, the lens layer comprises a plurality of lenses corresponding to the plurality of light-emitting regions, an orthographic projection of each of the lenses on the display panel covers the corresponding light-emitting region, and a refractive index of the lens is greater than that of the third insulative layer.

16. A display device, wherein the display device comprises a power supply assembly and a display module; and
the power supply assembly is connected to the display module for supplying power to the display module;
wherein the display module comprises:
a display panel, having an active face and a non-active face opposite to each other, the display panel comprising a plurality of light-emitting regions arranged at intervals, wherein the light-emitting regions are configured to emit light; and
a light-dimming assembly, disposed on the active face of the display panel and configured to modulate an angle of emergent light of the display panel, wherein the light-dimming assembly comprises:
a first insulative layer, provided with openings, wherein the opening at least has a side wall, an orthographic projection of each of the openings on the display panel is disposed at a spacing between two adjacent light-emitting regions; and
a light-absorbing layer, comprising a light-absorbing structure, wherein the light-absorbing structure is arranged corresponding to the opening and configured to absorb light, the light-absorbing structure comprises a first light-absorbing portion disposed in the corresponding opening and a second light-absorbing portion disposed on a side, away from the display panel, of the first insulative layer, the first light-absorbing portion is disposed in the opening, an orthographic projection of the second light-absorbing portion on the display panel at least surrounds an orthographic projection of the first light-absorbing portion on the display panel, and the orthographic projection of the second light-absorbing portion on the display panel is not overlapped with the light-emitting region.

17. The display device according to claim 16, wherein a depth of the opening equals a thickness of the first insulative layer; and
a length of the first light-absorbing portion in a first direction equals the depth of the opening, a surface of the first light-absorbing portion is partially in contact with the active face of the display panel, and the first direction is perpendicular to the active face of the display panel.

18. The display device according to claim 16, wherein the orthographic projection of the second light-absorbing portion on the display panel covers the orthographic projection of the first light-absorbing portion on the display panel; and
a surface, away from the display panel, of the second light-absorbing portion is a planar surface.

19. The display device according to claim 16, wherein the orthographic projection of the second light-absorbing portion on the display panel covers the orthographic projection of the first light-absorbing portion on the display panel; and
a surface, away from the display panel, of the second light-absorbing portion is a non-planar surface, and a thickness of a portion, close to the opening, of the second light-absorbing portion is less than that of a portion, away from the opening, of the second light-absorbing portion.

20. The display device according to claim 19, wherein the surface, away from the display panel, of the second light-absorbing portion is recessed in a direction close to the display panel.
